(19) United States
(12) Patent Application Publication
(10) Pub. No.: US 2006/0022274 A1
(43) Pub. Date: Feb. 2, 2006

(54) Semiconductor integrated circuit device

(76) Inventors: Hisashi Hasegawa, Chiba-shi (JP); Yoshifumi Yoshida, Chiba-shi (JP)

Correspondence Address: BRUCE L. ADAMS, ESQ., 17 BATTERY PLACE-SUITE 1231, NEW YORK, NY, 10004, US

(21) Appl. No.: 11/178,744

(22) Filed: Jul. 11, 2005

(30) Foreign Application Priority Data
Jul. 14, 2004 (JP) 2004-207225

(51) Int. Cl. H01L 23/62

(52) U.S. Cl. 257/358; 257/350; 257/355; 257/357; 257/359; 257/363

(57) ABSTRACT

Provided is a structure in which a gate electrode of an MMOS transistor of a fully depleted SOT CMOS circuit formed on a semiconductor thin film has an N-type conductivity, while a gate electrode of an protection NMOS transistor as an ESD input/output protection element formed on a semiconductor support substrate has a P-type conductivity, making it possible to protect input/output terminals, especially, an output terminal of a fully depleted SOI CMOS device, which is weak against ESD noise, while ensuring a sufficient ESD breakdown strength.

### BACKGROUND OF THE INVENTION

1. Field of the Invention

The present invention relates to a semiconductor integrated circuit device, in particular, to an electrostatic discharge (ESD) protection device for SOI structure.

2. Description of the Related Art

In a semiconductor integrated circuit device including a resistor circuit composed of a resistor made of polysilicon or the like, an input or output protection element made up of a diode or a MOS transistor is generally disposed between an internal circuit and an external input/output terminal to prevent breakdown of internal elements composing the internal circuit when an excess amount of current flows into the circuit from outside by static electricity.

FIGS. 2A to 2C show examples of an input/output circuit unit in a conventional semiconductor integrated circuit device having such protection circuits. In FIG. 2A, a CMOS inverter composed of an N-channel MOS transistor 113 and a P-channel MOS transistor 112 is illustrated as an internal element 10 of a CMOS structure. N-channel MOS transistors are provided as protection elements 20 between the CMOS inverter and both an input terminal 301 and an output terminal 302, and between a Vdd line 303 and a Vss line 304. Note that the circuit configuration of the internal element is illustrated as the CMOS inverter for ease of explanation.

With the above configuration, when a negative overvoltage is applied to the input or output terminal, for example, a forward voltage is attained at a PN junction of one of the NMOS transistors of the protection elements 20, so current flows in the protective NMOS transistor to protect the internal element. In contrast, when a positive overvoltage is applied, current flows in one the protective NMOS transistors by avalanche breakdown at the PN junction of the NMOS transistor in the protection elements 20. In this way, overcurrent is directly guided to a grounded substrate by way of the input/output protection element and thus kept from flowing in the internal element.

Input/output protection for an NMOS transistor 113 composing the internal element 10 in FIG. 2B, and that for a PMOS transistor 112 composing the internal element 10 in FIG. 2C, are directed to ESD protection in the same manner.

Generally a device element formed on an SOI substrate, especially, on a thin-film SOI substrate is easy to break down by heat generation due to overcurrent since a buried insulating film and an isolation insulating film surround it, and it has low heat dissipation ability. As a result, an SOI device is structurally weak against ESD.

It follows that the ESD protection element formed on an SOI semiconductor thin film easily breaks down. To overcome such a problem, various devices for attaining a sufficient ESD strength have been hitherto made. For example, in a semiconductor integrated circuit device where a CMOS buffer ESD protection circuit is formed on an SOI substrate as an input protection element for an internal element, a PNP or NPN diode is additionally provided in front of the CMOS buffer ESD-protection circuit to enhance the ESD strength (see JP 3447372 B (p. 6, FIG. 2), for example).

As mentioned above, the formation of the ESD protection element on the SOI substrate involves enlarging the protection element or increasing the number of protection elements for attaining a sufficient ESD strength, and is disadvantageous in extension of the protection circuit and chip area.

Meanwhile, as one way to attain the sufficient ESD strength, JP 04-345064 A (p. 9, FIG. 1) and JP 08-181219 A (p. 5, FIG. 1) disclose a semiconductor integrated circuit device where an internal element 10 is formed in an SOI semiconductor thin film and an input protection element is formed on a semiconductor support substrate, for example.

However, when the semiconductor thin film or buried insulating film of the SOI substrate is partially removed to expose the semiconductor support substrate, and the protection element is formed on the exposed portion, the protection element itself can secure a sufficient ESD strength but a problem comes out that the internal element easily breaks down.

This is because, in a general circuit design, when an ESD noise enters, the noise is supposed to get out through the ESD protection element in advance to the internal element. However, when the withstand voltage of the ESD protection element on the semiconductor support substrate is too high, the protection element cannot react to the ESD noise introduced from the output terminal 302, and the noise enters the internal element on the SOI semiconductor thin film resulting in the breakdown of the internal element. Accordingly the ESD protection element on the semiconductor support substrate should be designed to ensure high breakdown strength in one-way and keep the withstand voltage of the ESD protection lower than that of the internal element.

### SUMMARY OF THE INVENTION

In order to solve the above-mentioned problem, the present invention employs the following means.

(1) A semiconductor integrated circuit device includes: a CMOS element composed of a first X-channel MOS transistor and a first P-channel MOS transistor that are formed on a semiconductor thin film on an insulating film formed on a semiconductor support substrate with the semiconductor thin film and the insulating film composing a silicon-on-insulator (SOI) substrate; a resistor; and a second N-channel MOS transistor serving as an ESD protection element having an electrostatic discharge ability and protecting one of an input terminal and an output terminal, in which a gate electrode of the first N-channel MOS transistor serving as an active element and formed on the semiconductor thin film has an N-type conductivity, a gate electrode of the first P-channel MOS transistor has a P-type conductivity, and a gate electrode of the second N-channel MOS transistor serving as the ESD protection element has a P-type conductivity.

(2) In the semiconductor integrated circuit device, the second N-channel MOS transistor as the ESD protection element is formed on the semiconductor support substrate exposed by removing a part of the semiconductor thin film of the SOI substrate and a buried insulating film.

(3) In the semiconductor integrated circuit device, an N-type gate electrode of the first N-channel MOS transistor, a P-type gate electrode of the first P-channel MOS transistor, and a gate electrode of the second N-channel MOS transistor serving as the ESD protection elements are formed of a first polysilicon.

(4) In the semiconductor integrated circuit device according to the item (1) or (2), an N-type gate electrode of the first N-channel MOS transistor, a P-type gate electrode of the first P-channel MOS transistor, and a P-type gate electrode of the second N-channel MOS transistor serving as the ESD protection element have a polycide structure as a laminate structure of a first polysilicon and high melting-point metal silicide.

(5) In the semiconductor integrated circuit device, the resistor is formed of a second polysilicon whose thickness is different from the first polysilicon forming the gate electrodes of the first N-channel MOS transistor and the first P-channel MOS transistor as the active elements, and the second N-channel MOS transistor as the ESD protection-element.

(6) In the semiconductor integrated circuit device, the resistor is made of single-crystal silicon for the semiconductor thin film.

(7) In the semiconductor integrated circuit device, the resistor is a thin-film metal resistor made of an Ni—Cr alloy, or chromium silicide, molybdenum silicide, or β-ferrite silicide.

(8) In the semiconductor integrated circuit device, the semiconductor thin film forming the SOI substrate has a thickness of 0.05 μm to 0.2 μm.

(9) In the semiconductor integrated circuit device, the insulating film forming the SOI substrate has a thickness of 0.1 μm to 0.5 μm.

(10) In the semiconductor integrated circuit device, the insulating film forming the SOI substrate is made of an insulating material including glass, sapphire, or ceramics including silicon oxide or silicon nitride.

As set forth above, in the semiconductor integrated circuit device, the gate electrode of the NMOS transistor as an internal element formed on the semiconductor thin film has N-type conductivity, while the gate electrode of the protection NMOS transistor as an ESD input/output protection element formed on the semiconductor support substrate has P-type conductivity, making it possible to reduce leak current and to shorten the gate length of the protection NMOS transistor. Ensuring a high ESD breakdown strength owing to the formation on the support substrate, the protection NMOS transistor absorbs ESD noise first to protect an input/output terminal of the internal element on the semiconductor thin film, which is weak against the ESD noise, especially, to protect the output terminal. In particular, a protection effect can be greatly exerted in a power management semiconductor integrated circuit device or analog semiconductor integrated circuit device in which electrical input/output characteristics are important.

### BRIEF DESCRIPTION OF THE DRAWINGS

In the accompanying drawings:

FIG. 1 is a schematic sectional diagram showing a semiconductor integrated circuit device according to an embodiment of the present invention;

FIGS. 2A to 2C are circuit diagrams showing a protection circuit for an internal element;

FIG. 3 is a schematic sectional diagram showing a semiconductor integrated circuit device according to another embodiment of the present invention;

FIG. 4 is a schematic sectional diagram showing a semiconductor integrated circuit device according to another embodiment of the present invention;

FIG. 5 is a schematic sectional diagram showing a semiconductor integrated circuit device according to another embodiment of the present invention;

FIG. 6 is a schematic sectional diagram showing a semiconductor integrated circuit device according to another embodiment of the present invention;

FIG. 7 is a schematic sectional diagram showing a semiconductor integrated circuit device according to another embodiment of the present invention;

FIG. 8 is a schematic sectional diagram showing a conventional semiconductor integrated circuit device; and

FIG. 9 is a schematic sectional diagram showing a conventional semiconductor integrated circuit device.

### DETAILED DESCRIPTION OF THE PREFERRED EMBODIMENTS

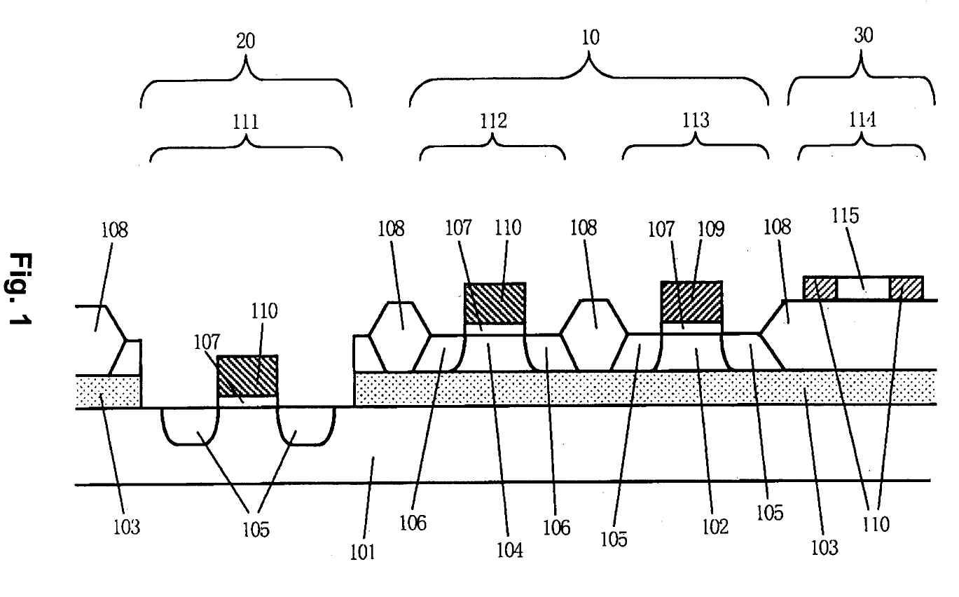

Hereinafter, embodiments of the present invention will be described in detail with reference to the accompanying drawings. FIG. 1 is a schematic sectional diagram showing a semiconductor integrated circuit device according to an embodiment of the present invention.

A silicon-on-insulator (SOI) substrate is composed of, for example, a semiconductor support substrate 101 of a P-type conductivity, which is made of single crystal, a buried insulating film 103, and a semiconductor thin film 102 of a P-type conductivity, which is made of single crystal and is used to form elements. Formed on the P-type semiconductor thin film 102 are a CMOS inverter as an internal element 10 composed of a first N-channel MOS transistor (hereinafter abbreviated to “NMOS”) 113 and a first P-channel MOS transistor (hereinafter abbreviated to “PMOS”) 112, and a P⁻ resistor 114 made of polysilicon as a resistor element 30. However, the internal element 10 is not limited to the CMOS inverter but can be arbitral set.

Further formed on the semiconductor support substrate 101 is an ESD protective transistor composed of a second NMOS transistor as a protection element (hereinafter referred to as “protection NMOS transistor”) 111 to thereby complete a semiconductor integrated circuit device.

A thin-film SOI device, especially, a fully depleted (FD) SOI device, which is ideal for low-voltage operation or low power consumption, employs a so-called homopolar gate structure for the CMOS structure. This homopolar gate structure is such that an N+ polysilicon 109 forms a gate electrode of the NMOS transistor 113, and P+ polysilicon forms a gate electrode of the PMOS transistor 112. The CMOS inverter of FIG. 1 has a similar structure as shown later. Hereafter, description will be made on the SOI device of the FD structure by way of example. The polysilicon forming the gate of the transistor is defined as a first polysilicon.

To begin with, the NMOS transistor 113 is composed of an N+ impurity diffusion layer 105 serving as a source/drain region and formed in the P-type semiconductor thin film 102, and a gate electrode made of the N+ polysilicon 109 formed on a gate insulating film 107 as a silicon oxide film, for example. The PMOS transistor 112 is composed of a P+ impurity diffusion layer 106 serving as a source/drain region formed in an N-type well formed in the P-type semiconductor thin film, and the gate electrode made of a P+ polysilicon 110 formed on the gate insulating film 107 made of, for example, silicon oxide. The NMOS transistor 113 and the PMOS transistor 112 are completely isolated from each other by means of a field insulating film 108 formed through local oxidation of silicon (LOCOS method), for example, and the buried insulating film 103.

In addition, the P⁻ resistor of a high resistance constituting the resistor element 30 is formed on the field insulating film, for example, which is used for a bleeder voltage divider circuit for dividing voltage as an analog circuit or a CR circuit for setting a time constant. In this embodiment, the P⁻ resistor is made of polysilicon.

Next, the protection NMOS transistor 111 forming the protection element 20 is composed of an N+ impurity diffusion layer 105 serving as a source/drain region formed on the exposed semiconductor support substrate where the semiconductor thin film 102 and the buried insulating film 103 are partially removed to expose the semiconductor Support substrate 101, and a gate electrode made of polysilicon (P+ polysilicon 110), whose conductivity is inverse to that of the NMOS transistor 113 of the internal element, disposed on a gate insulating film 107 made of oxide film for example.

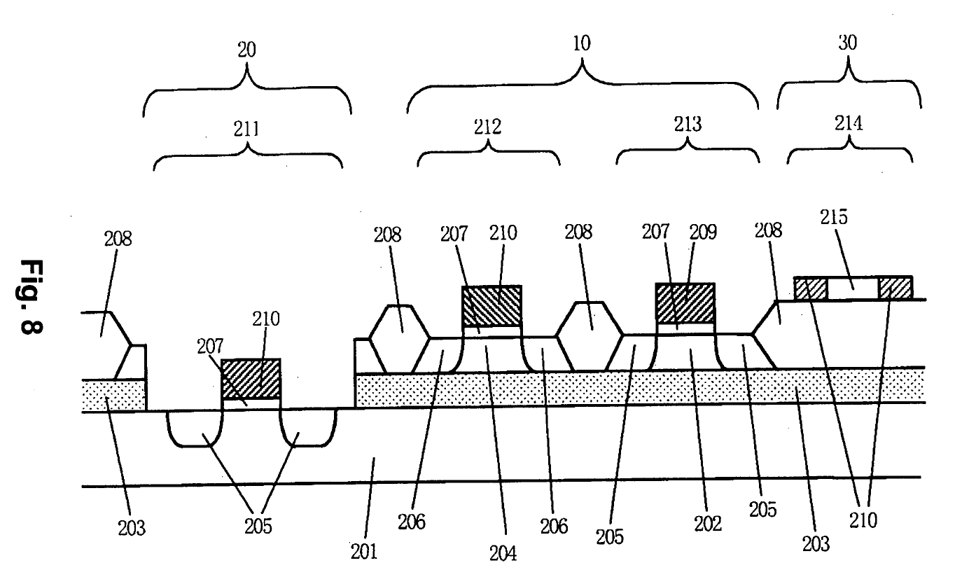

In the conventional structure of FIG. 8, a protection NMOS transistor 211 and an NMOS transistor 213 of an internal element have the same gate structure in that gate electrodes are formed of an N+ polysilicon 209. As a result, a threshold voltage of the protection NMOS transistor 211 is substantially the same as the NMOS transistor 213 of the internal element as an FD SOI device, for example, about 0 to 0.3 V. Thus, in order to reduce a leak current in an ESD protection element not functioning as an active element, impurities are doped into a channel region through ion implantation (called “channel doping”) to increase an impurity concentration of the substrate to set the threshold voltage of the protection NMOS transistor 211 to 1 V or higher.

In contrast, as in the embodiment of FIG. 1, the P+ polysilicon 110 is used for the gate electrode of the protection NMOS transistor 111, whereby a threshold voltage can be easily set to 1 V or higher even without a channel doping step due to a difference in work function between the gate electrode and the semiconductor thin film. Since the threshold voltage can be further increased by adding channel doping, a gate length of the protection NMOS transistor 111 can be reduced without increase in leak current, and ESD noise can be dissipated first by punch-through before reaching the internal element composed of the SOI device of the FD structure.

Note that the P+ polysilicon 110 forming the P-type gate electrode contains acceptor impurities such as boron or BF₂ in a concentration of 1×10¹⁸ atoms/cm³ or higher. The N+ polysilicon 109 forming the N-type gate electrode contains donor impurities such as phosphorous or arsenic in a concentration of 1×10¹⁸ atoms/cm³ or higher.

The N+ impurity diffusion layers 105 as the source/drain region of the NMOS transistor 113 of the internal element 10 and the protection NMOS transistor 111 of the protection element 20 contain phosphorous or arsenic at a concentration of 1×10¹⁹ atoms/cm³ or higher. At this time, the N+ impurity diffusion layers 105 of the NMOS transistor 113 and the protection NMOS transistor 111 may both be formed of phosphorous or arsenic. Alternatively, the N+ impurity diffusion layer 105 of the NMOS transistor 113 may be formed of arsenic, while the N+ impurity diffusion layer 105 of the protection NMOS transistor 111 may be formed of phosphorous, vise versa.

The P+ impurity diffusion layer 106 as the source/drain region of the PMOS transistor 112 may be formed of boron or BF₂ at a concentration of 1×10¹⁹ atoms/cm³ or higher.

The thicknesses of the semiconductor thin film 102 and buried insulating film 103 of the SOI substrate are determined according to its operation voltage. The buried insulating film 103 is mainly made of a silicon oxide film with the thickness of 0.1 μm to 0.5 μm. Note that the buried insulating film can be made of glass, sapphire, silicon nitride film, or the like. The thickness of the semiconductor thin film 102 is determined according to the function and performance of the fully depleted (FD) SOT device as a thin-film SOI device, and is set to 0.05 μm to 0.2 μm.

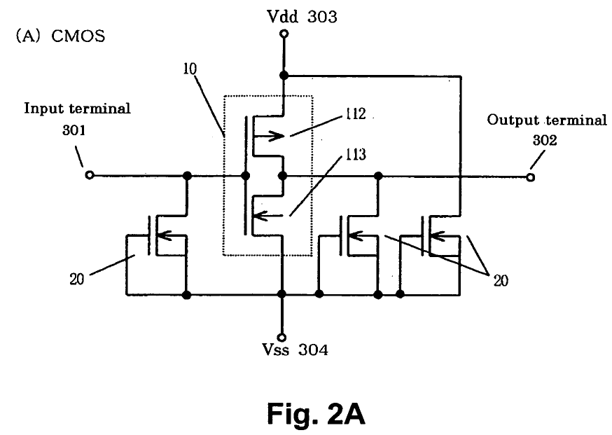

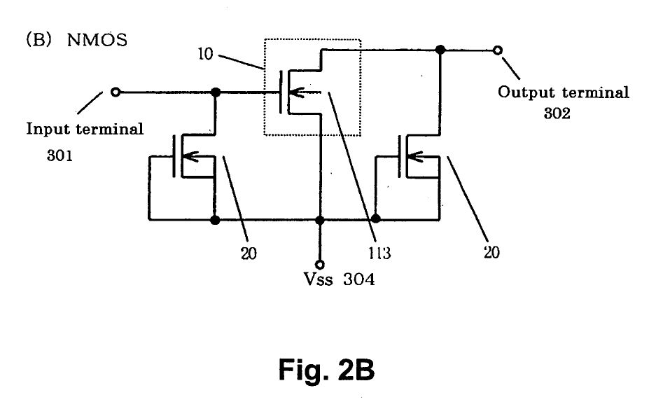

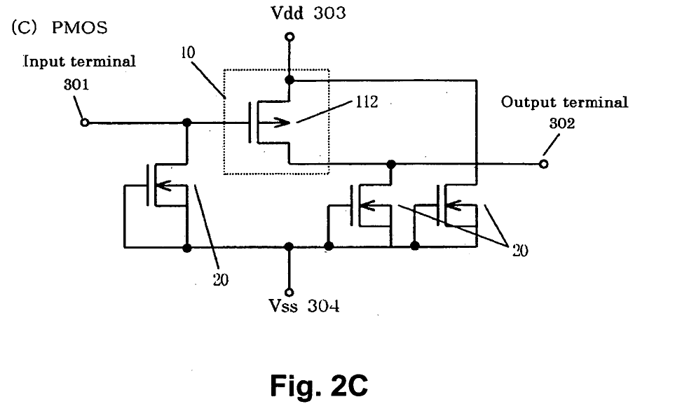

Further, in the embodiment of FIG. 1, the P⁻ resistor 114 of the resistor element 30 used in an analog circuit is made of a second polysilicon whose thickness is thinner than the gate electrode formed in a step different from the step of forming the gate electrodes of the CMOS inverter using the polysilicon 109 and polysilicon 110. For example, the thickness of the gate electrode is set to about 2,000 to 6,000 Å, while the thickness of the P⁻ resistor 114 is set to 500 to 2, 500 Å. This is because a resistor formed of polysilicon with smaller thickness can realize higher sheet resistance and better temperature characteristics for higher accuracy. The sheet resistance is set to several kΩ/□ to several tens of kΩ/□ in a general voltage divider circuit, although it varies depending on the application of a resistor. At this time, boron or BF₂ is doped as impurities in a concentration of about 1×10¹⁴ to 9×10¹⁸ atoms/cm³. FIG. 1 shows the P⁻ resistor 114, but a P+ resistor of a low resistance or an N-type resistor of an inverse impurity polarity can be used in consideration of characteristics of those resistors and characteristics required for semiconductor products. Note that the ESD strength can be enhanced by inserting the resistor element 30 between an input terminal 301 or output terminal 302 and the internal element 10 of FIGS. 2A to 2C.

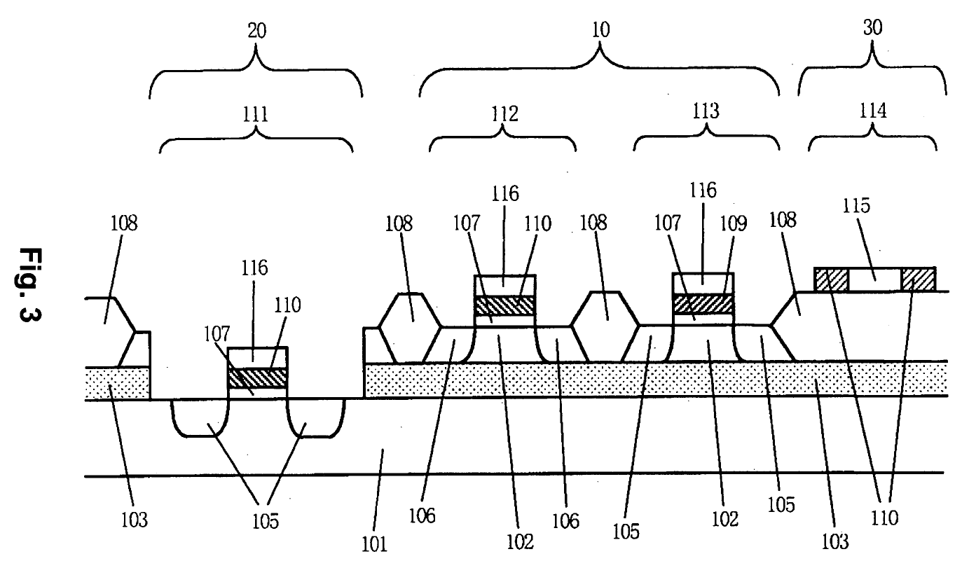

FIG. 3 is a schematic diagram showing a semiconductor integrated circuit device according to another embodiment of the present invention. In the embodiment of the present invention shown in FIG. 1, the gate electrode is made of a single layer of polysilicon. Particularly in this case, the sheet resistance realized by the single layer of the P+ polysilicon 110 is as large as about 100 Ω/□, which hinders the application to a semiconductor device required to operate at high speed with high frequency. As a countermeasure against this drawback, devised is a structure of FIG. 3, where a gate electrode has a so-called polycide structure in which a high melting-point metal silicide 116 such as tungsten silicide, molybdenum silicide, titanium silicide, or platinum silicide is deposited on the N+ polysilicon 109 and the P+ polysilicon 110 to reduce the gate resistance. Standard sheet resistance is several Ω/□ to over ten Ω/□ under the condition that the thickness ranges from 500 Å to 2,500 Å, although it varies depending on the type and film thickness of the high melting-point metal silicide.

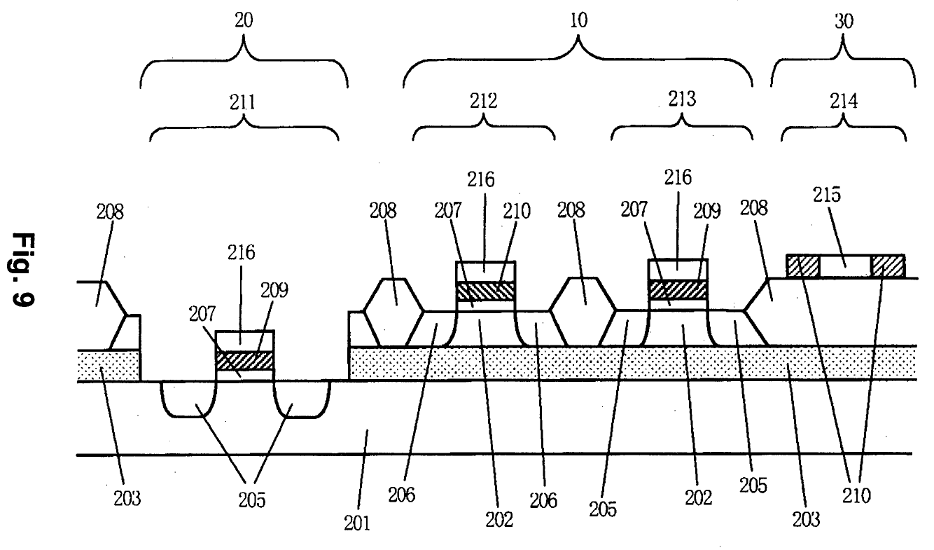

However, as shown in FIG. 9, in the conventional semiconductor device of the polycide gate structure, the NMOS transistor 213 and the protection NMOS transistor 211 have the same gate structure in which the gate electrodes are formed of the N+ polysilicon 209. According to the present invention as shown in FIG. 3, since the NMOS transistor 113 has the N+ type gate electrode, while the protection NMOS transistor 111 solely has the P+ type gate electrode, the gate length of the protection NMOS transistor 111 can be reduced. Consequently, the ESD noise can be dissipated without breakdown of the internal element.

In addition, the MOS transistor operation itself depends on the work function difference between the semiconductor thin film, and the N+ polysilicon 109 and the P+ polysilicon 110, whereby the semiconductor device can improve its performance accordingly as the gate electrode resistance is lowered.

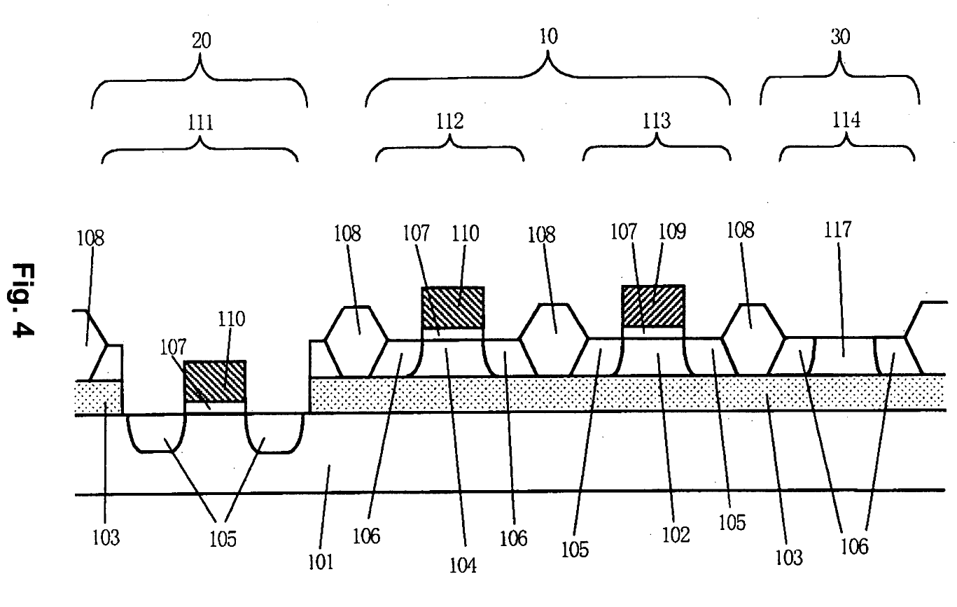

Referring next to FIGS. 4 to 7, description will be made of another structure of the semiconductor integrated circuit device according to the embodiment of the present invention as shown in FIGS. 1 and 3. FIG. 4 is a schematic sectional diagram of another Structure of the semiconductor integrated circuit device of the present invention as shown in FIG. 1.

The structure illustrated in FIG. 4 also includes the CMOS inverter 11 as the internal element, the protection element 20 made up of the P+ gate protection NMOS transistor 111 aiming at ESD protection for input/output terminals of the internal element, and the resistor element 30 used in the analog circuit, which are the basic components of the present invention, but differs from that of FIG. 1 in that the resistor element 30, for example, the P resistor 114 is formed of single-crystal silicon of the semiconductor thin film, not the polysilicon.

Since highly accurate divided voltage by bleeder voltage divider circuit is needed in analog circuit, high accuracy in resistance ratio is required for a bleeder resistor. For example, with a voltage detector (hereinafter, referred to as “VD”) or the like, a resistor circuit occupies a very large area relative to the entire chip area. Thus, if the area of the resistor element can be reduced with high precision, the chip are a accordingly reduces, enabling cost reduction.

When the resistor is formed using the semiconductor thin film of the SOI substrate as the single-crystal silicon, no crystal grain boundary exist in the resistor, so the resistor is completely free of a resistance variation dependent on the grain boundary, and it is possible to both increase a resistance of the resistor and reduce an area of the resistor. As a result, such a resistor effectively functions. Note that the semiconductor integrated circuit device according to the embodiment of the present invention as shown in FIG. 4 has just the same function and effect as the semiconductor integrated circuit device of FIG. 1.

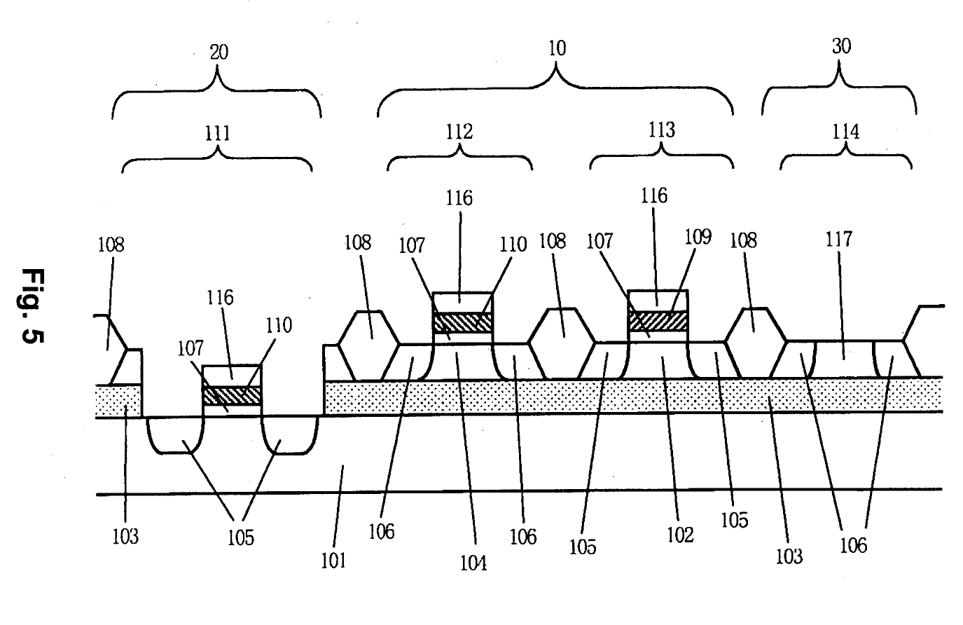

FIG. 5 is a schematic sectional diagram showing another structure of the semiconductor integrated circuit device of the present invention as shown in FIG. 3. This structure is similar to that of FIG. 4 in that the resistor element 30, for example, the P⁻ resistor 114 is formed of single-crystal silicon of the semiconductor thin film, not polysilicon. Note that the semiconductor integrated circuit device as shown in FIG. 5 has just the same function and effect as the semiconductor integrated circuit device of FIG. 3 and the same advantages as the resistor formed of single-crystal silicon shown in FIG. 4.

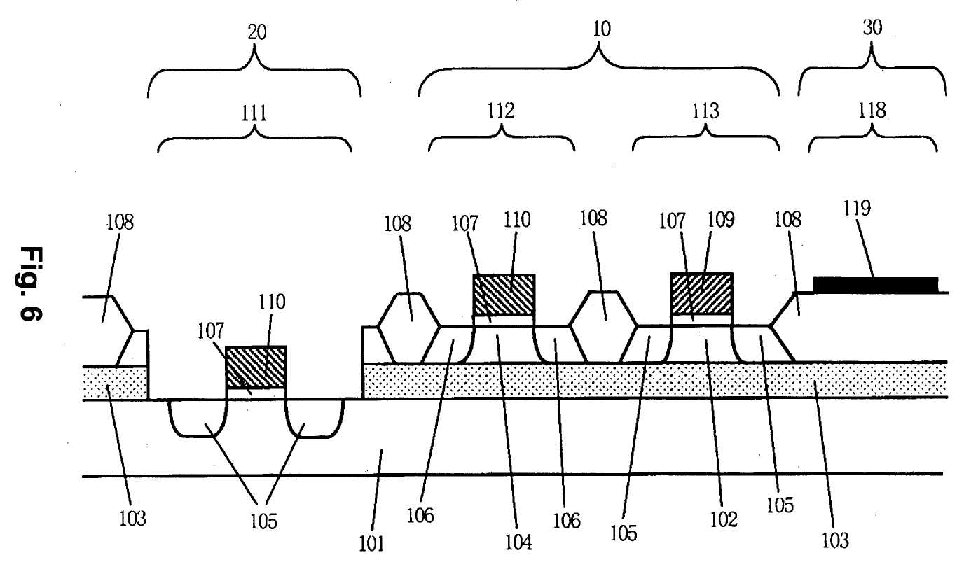

FIG. 6 is a schematic sectional diagram showing another structure of the semiconductor integrated circuit device of the present invention as shown in FIG. 1. The structure illustrated in FIG. 6 also includes the CMOS inverter 11 as the internal element, the protection element 20 made up of the P+ gate protection NMOS transistor 111 aiming at ESD protection for input/output terminals of the internal element, and the resistor element 30 used in the analog circuit, which are the basic components of the present invention, but differs from that of FIG. 1 in that a thin-film metal resistor 118 is used as the resistor element 30 instead of the polysilicon.

In the embodiment shown in FIG. 6, a chromium silicide 119 is used as the thin-film metal resistor 118 but an Ni—Cr alloy, or a metal silicide such as molybdenum silicide or β-ferrite silicide can be used. The chromium silicide is high in resistance among metal silicides, and thus can be used as a resistor if deposited into a film as thin as about 100 Å to 300 Å. The thin-film metal resistor 118 is used in place of the polysilicon, whereby variations in resistance ratio and resistance value of the voltage divider circuit, and temperature coefficients can be reduced. Note that the semiconductor integrated circuit device according to the embodiment of the present invention as shown in FIG. 6 has just the same function and effect as the semiconductor integrated circuit device of FIG.

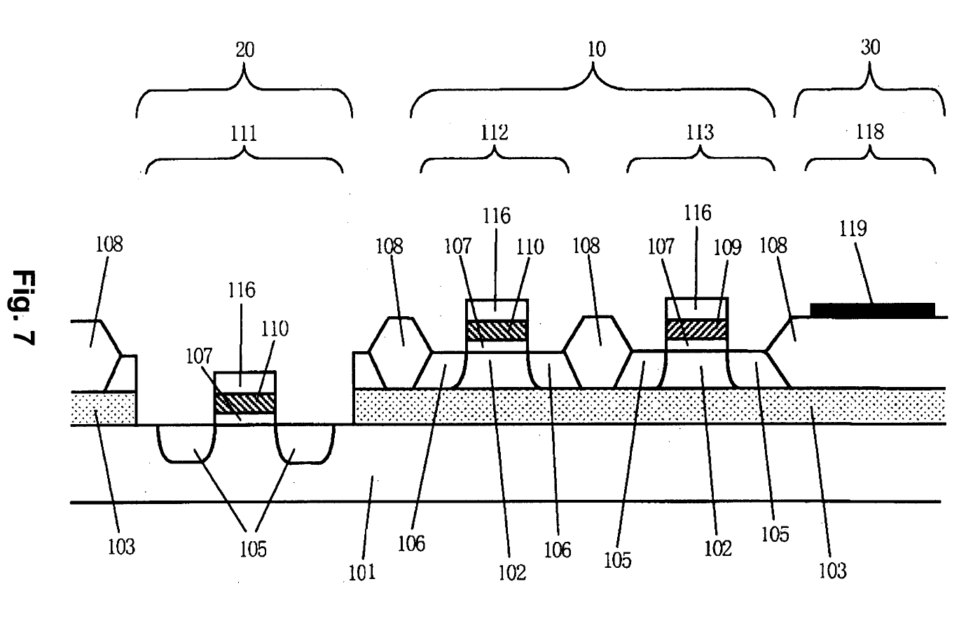

FIG. 7 is a schematic sectional diagram showing another structure of the semiconductor integrated circuit device of the present invention as shown in FIG. 3. This structure is similar to that of FIG. 6 in that the thin-film metal resistor 118 is used as the resistor element 30 instead of polysilicon. Note that the semiconductor integrated circuit device as shown in FIG. 6 has the same function and effect as the semiconductor integrated circuit device of FIG. 3 and the same advantages as the resistor formed of thin-film metal shown in FIG. 5.

The embodiment mode of the present invention has been described by way of embodiments employing the SOI substrate made up of the P-type semiconductor support substrate and the P-type semiconductor thin film. However, an SOI substrate composed of an N-type semiconductor support substrate and an N-type semiconductor thin film may be used. At this time, it is possible to set the withstand voltage for the ESD protection lower than the withstand voltage for the internal element of the thin-film SOI device while securing the high ESD breakdown strength, and dissipate the ESD noise first from the internal element as in the above-mentioned example or principles for an protection NMOS transistor including an N-type substrate, a P-type well, and a P+ gate and formed on the N-type semiconductor support substrate.

In addition, examples of the SOI substrate include a bonded SOI substrate manufactured by bonding semiconductor thin films forming an element, and a SIMOX substrate manufactured by implanting oxygen ions into a semiconductor substrate, followed by heat treatment to form a buried oxide film, both of which can be used in the present invention. Further, in the case of using the bonded SOI substrate, the semiconductor thin film and the semiconductor substrate may be different in conductivity.

The present invention can be used for improving electrostatic discharge (ESD) breakdown characteristics of the fully depleted SOI CMOS semiconductor device including the resistor circuit. In particular, the present invention can be used for improving electrostatic discharge (ESD) characteristics of a power management semiconductor integrated circuit device such as a voltage detector (VD), a voltage regulator (hereinafter referred to as “VR”), a switching regulator (hereinafter, referred to as “SWR”), or a switched capacitor, and an analog semiconductor integrated circuit device such as an operational amplifier or a comparator.

What is claimed is:

1. A semiconductor integrated circuit device, comprising:
a CMOS element containing a first N-channel MOS transistor whose gate electrode has an N-type conductivity and a first P-channel MOS transistor whose gate electrode has a P-type conductivity both of which are disposed in a semiconductor thin film of an SOI substrate comprising a semiconductor support substrate, a buried insulating film disposed on the semiconductor support substrate, and the semiconductor thin film disposed on the buried insulating film;
a resistor disposed in the SOI substrate; and
a second N-channel MOS transistor whose gate electrode has a P-type conductivity, disposed in the SOI substrate and serving as an ESD protection element having an electrostatic discharge ability and protecting one of an input terminal or an output terminal.

2. A semiconductor integrated circuit device according to claim 1, wherein the second N-channel MOS transistor as the ESD protection element is disposed in the semiconductor support substrate exposed by removing a part of the semiconductor thin film and a buried insulating film of the SOI substrate.

3. A semiconductor integrated circuit device according to claim 1, wherein the N-type gate electrode of the first N-channel MOS transistor, the P-type gate electrode of the first P-channel MOS transistor, and the P-type gate electrode of the second N-channel MOS transistor serving as the ESD protection element are formed of a first polysilicon.

4. A semiconductor integrated circuit device according to claim 2, wherein the N-type gate electrode of the first N-channel MOS transistor, the P-type gate electrode of the first P-channel MOS transistor, and the P-type gate electrode of the second N-channel MOS transistor serving as the ESD protection element are formed of a first polysilicon.

5. A semiconductor integrated circuit device according to claim 1, wherein the N-type gate electrode of the first N-channel MOS transistor, the P-type gate electrode of the first P-channel MOS transistor, and the P-type gate electrode of the second N-channel MOS transistor serving as the ESD protection element have a polycide structure as a laminate structure of the first polysilicon and a high melting-point metal silicide.

6. A semiconductor integrated circuit device according to claim 2, wherein the N-type gate electrode of the first N-channel MOS transistor, the P-type gate electrode of the first P-channel MOS transistor, and the P-type gate electrode of the second N-channel MOS transistor serving as the ESD protection element have a polycide structure as a laminate structure of the first polysilicon and a high melting-point metal silicide.

7. A semiconductor integrated circuit device according to claim 1, wherein the resistor is formed of a second polysilicon whose thickness is different from the first polysilicon forming the gate electrodes of the first N-channel MOS transistor and the first P-channel MOS transistor, and the second N-channel MOS transistor.

8. A semiconductor integrated circuit device according to claim 2, wherein the resistor is formed of a second polysilicon whose thickness is different from the first polysilicon forming the gate electrodes of the first N-channel MOS transistor and the first P-channel MOS transistor, and the second N-channel MOS transistor.

9. A semiconductor integrated circuit device according to claim 1, wherein the resistor is made of single-crystal silicon comprising the semiconductor thin film.

10. A semiconductor integrated circuit device according to claim 2, wherein the resistor is made of single-crystal silicon comprising the semiconductor thin film.

11. A semiconductor integrated circuit device according to claim 1, wherein the resistor is comprised of a thin-film metal resistor made of an Ni—Cr alloy, or chromium silicide, molybdenum silicide, or β-ferrite suicide.

12. A semiconductor integrated circuit device according to claim 2, wherein the resistor is comprised of a thin-film metal resistor made of an Ni—Cr alloy, or chromium silicide, molybdenum silicide, or β-ferrite silicide.

13. A semiconductor integrated circuit device according to claim 1, wherein the semiconductor thin film forming the SOI substrate has a thickness of 0.05 μm to 0.2 μm.

14. A semiconductor integrated circuit device according to claim 2, wherein the semiconductor thin film forming the SOI substrate has a thickness of 0.05 μm to 0.2 μm.

15. A semiconductor integrated circuit device according to claim 1, wherein the insulating film forming the SOI substrate has a thickness of 0.1 μm to 0.5 μm.

16. A semiconductor integrated circuit device according to claim 2, wherein the insulating film forming the SOT substrate has a thickness of 0.1 μm to 0.5 μm.

17. A semiconductor integrated circuit device according to claim 1, wherein the insulating film forming the SOI substrate is made of an insulating material including glass, sapphire, or ceramics including silicon oxide or silicon nitride.

18. A semiconductor integrated circuit device according to claim 2, wherein the insulating film forming the SOI substrate is made of an insulating material including glass, sapphire, or ceramics including silicon oxide or silicon nitride.
